(19) United States
(12) Patent Application Publication
(10) Pub. No.: US 2022/0028698 A1
(43) Pub. Date: Jan. 27, 2022

(54) METHOD FOR MAKING SEMICONDUCTOR SUBSTRATE AND METHOD FOR MAKING SEMICONDUCTOR DEVICE

(71) Applicant: FUJIAN JING'AN OPTOELECTRONICS CO., LTD., Quanzhou City (CN)

(72) Inventors: Juiping LI, Quanzhou City (CN); Bohsiang TSENG, Quanzhou City (CN); Jiahao ZHANG, Quanzhou City (CN); Zengwei LIU, Quanzhou City (CN); Mingxin CHEN, Quanzhou City (CN)

(21) Appl. No.: 17/494,191

(22) Filed: Oct. 5, 2021

Related U.S. Application Data
(63) Continuation-in-part of application No. PCT/CN2020/101293, filed on Jul. 10, 2020.

(30) Foreign Application Priority Data
Jun. 16, 2020 (CN) 202010547979.X

(51) Int. Cl. H01L 21/324; H01L 21/02; H01L 21/306; H01L 33/00

(52) U.S. Cl. CPC H01L 21/324; H01L 33/0095; H01L 21/306; H01L 21/02024

(57) ABSTRACT

A method for making a semiconductor substrate includes: cutting an ingot to obtain a plurality of substrates, each of the substrates including a first surface and a second surface opposite to the first surface; performing a surface treatment on at least one of the first surface and the second surface of each of the substrates using a surface-treating agent; annealing the substrates; and abrasing each of the annealed substrates. A method for making a semiconductor device is also disclosed.

### CROSS-REFERENCE TO RELATED APPLICATION

This application is a bypass continuation-in-part (CIP) application of PCT International Application No. PCT/CN2020/101293, filed on Jul. 10, 2020, which claims priority of Chinese Invention Patent Application No. 202010547979.X, filed on Jun. 16, 2020. The entire content of the international patent application is incorporated herein by reference.

### FIELD

The disclosure relates to a method for making a semiconductor substrate, and a method for making a semiconductor device using the semiconductor substrate.

### BACKGROUND

In a manufacturing process of semiconductor devices, a substrate is usually necessary for growing an epitaxial layer, and thus, manufacturing the substrate are particularly important. Generally, the steps of manufacturing a substrate include: crystal growth, cutting, abrasing, annealing, and polishing. The hardness of a substrate is a significant factor affecting the processing quality thereof. At present, most of the substrates used for preparing semiconductor devices are made of a material having a relatively high Mohs hardness. For example, sapphire has a Mohs hardness of 9. Materials with great hardness would cause difficulties during manufacturing of the substrate. For example, cutting and abrasing of the substrate made from a material having great hardness is difficult and time-consuming, and damages to the operating machines might occur, which increases the processing cost of such substrate. In addition, a material having great hardness directly affects the quality of the substrate, e.g., poor substrate quality, which might adversely affect the performance of the resultant semiconductor devices.

### SUMMARY

Therefore, an object of the disclosure is to provide a method for making a semiconductor substrate and a method for making a semiconductor device that can alleviate at least one of the drawbacks of the prior art.

According to a first aspect of the disclosure, the method for making the semiconductor substrate includes: cutting an ingot to obtain a plurality of substrates, each of the substrates including a first surface and a second surface opposite to the first surface; performing a surface treatment on at least one of the first surface and the second surface of each of the substrates using a surface-treating agent;

annealing the substrates so that the substrates react with the surface-treating agent to obtain annealed substrates, each of the annealed substrates having a base and a modified layer formed by a reaction between a corresponding one of the substrates and the surface-treating agent; and abrasing each of the annealed substrates to remove at least a part of the modified layer.

According to a second aspect of the disclosure, a method for making a semiconductor device, includes: providing a semiconductor substrate which is processed by the steps of: cutting an ingot to obtain a plurality of substrates, each of the substrates including a first surface and a second surface opposite to the first surface, performing a surface treatment on at least one of the first surface and the second surface of each of the substrates using a surface-treating agent, annealing the substrates so that the substrates react with the surface-treating agent to obtain annealed substrates, each of the annealed substrates having a base and a modified layer formed by a reaction between a corresponding one of the substrates and the surface-treating agent, and abrasing each of the annealed substrates to remove at least a part of the modified layer; forming at least one semiconductor layer on the semiconductor substrate; and etching the at least one semiconductor layer.

### BRIEF DESCRIPTION OF THE DRAWINGS

Other features and advantages of the disclosure will become apparent in the following detailed description of the embodiments with reference to the accompanying drawings, of which:

FIG. 1 is a flow diagram illustrating a method for making a semiconductor substrate in accordance with the present disclosure;

FIG. 2 is a schematic view illustrating a substrate having a first surface and a second surface in accordance with the present disclosure;

FIG. 3 is a schematic view of a first stacking example of the substrates subjected to a single-sided surface treatment;

FIG. 4 is a schematic view of a second stacking example of the substrates subjected to a double-sided surface treatment;

FIG. 5 is a schematic view of an embodiment of an annealed substrate having a base and a modified layer in accordance with the present disclosure;

FIGS. 6A and 6B are images of surface structures of substrates before and after the surface treatment, respectively;

FIG. 7 is a plot illustrating changes in removal rate of the annealed substrates and that of untreated substrates during an abrasing step, and the total removal rate of the annealed substrates and that of the untreated substrates in the abrasing step;

FIG. 8 is a plot illustrating changes in removal rate of the annealed substrates and that of untreated substrates during a polishing step, and the total removal rate of the annealed substrates and that of the untreated substrates in the polishing step;

FIG. 9 is an SEM image of a patterned substrate in accordance with the present disclosure, which is obtained by patterning the annealed substrate and formed with a plurality of protrusions;

FIG. 10 is a schematic view of a patterned substrate formed with the protrusions; and

FIG. 11 is a flow diagram illustrating a method for making a semiconductor device in accordance with the present disclosure.

### DETAILED DESCRIPTION

Before the disclosure is described in greater detail, it should be noted that where considered appropriate, reference numerals or terminal portions of reference numerals have been repeated among the figures to indicate corresponding or analogous elements, which may optionally have similar characteristics.

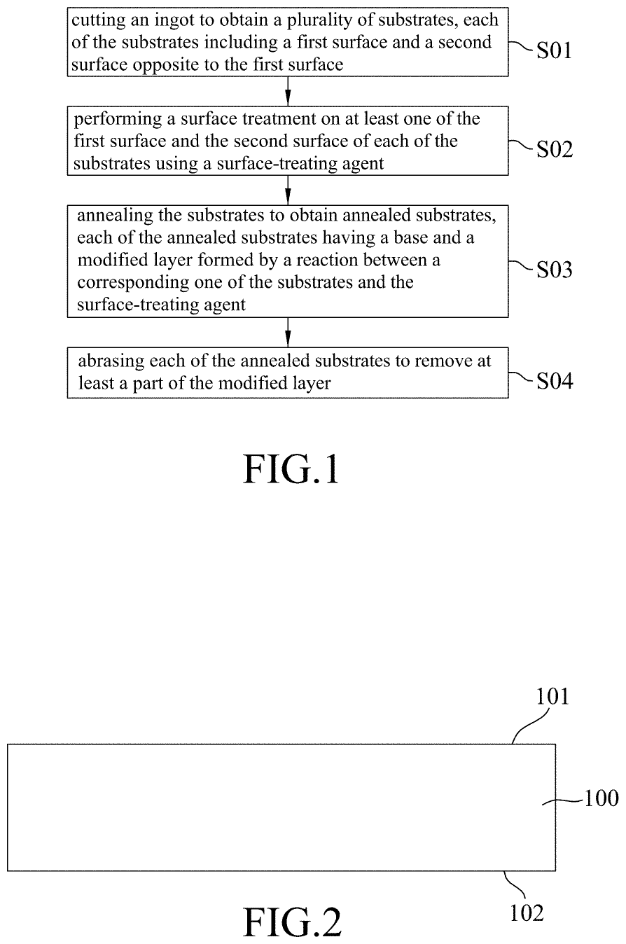

Referring to FIGS. 1 and 2, an embodiment of a method for making a semiconductor substrate in accordance with the disclosure at least includes:

Step S01: cutting an ingot to obtain a plurality of substrates 100, each of the substrates 100 including a first surface 101 and a second surface 102 opposite to the first surface 101;

Step S02: performing a surface treatment on at least one of the first surface 101 and the second surface 102 of each of the substrates 100 using a surface-treating agent 200;

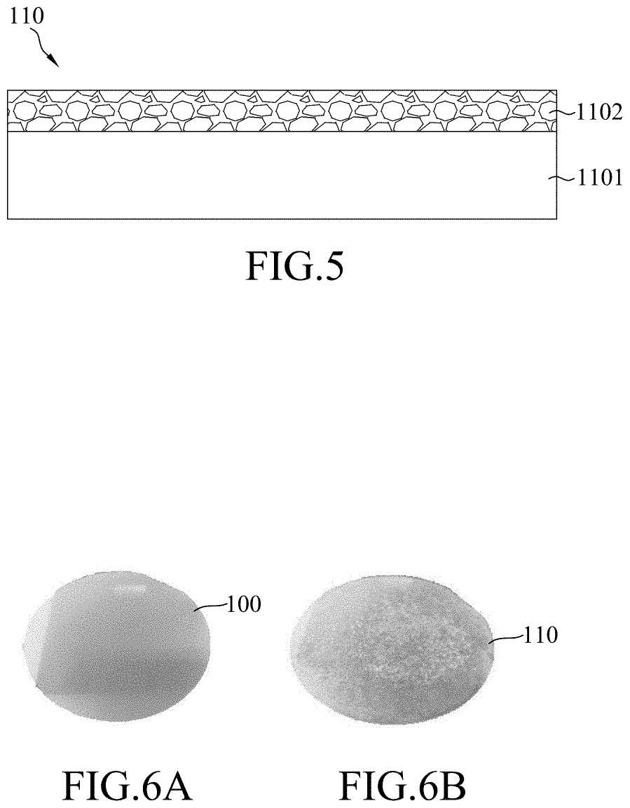

Step S03: annealing the substrates 100 so that the substrates 100 react with the surface-treating agent 200 to obtain annealed substrates 110, each of the annealed substrates 110 having a base 1101 and a modified layer 1102, the modified layer 1102 being formed by the reaction between a corresponding one of the substrates 100 and the surface-treating agent 200 (see FIG. 5); and

Step S04: abrasing each of the annealed substrates 110 to remove at least a part of the modified layer 1102.

In step S01, the substrates 100 may be any substrate that can be used to make a semiconductor device. For example, the substrates 100 may be made of, but not limited to, glass, elemental semiconductors (e.g., Group IV), compound semiconductors (e.g., Group IV compound semiconductors, III-V compounds, or II-VI compounds), metals, alloys, oxides, nitrides, halides, silicates, carbonates, etc.

In certain embodiments, the substrates 100 may be made of sapphire. A crystal growth procedure for sapphire substrates 100 is disclosed hereinafter. First, aluminum oxide (Al₂O₃) is placed in a crucible, followed by heating the crucible to a temperature of not less than 2000° C. such that the aluminum oxide in the crucible is in a molten state. Thereafter, the temperature of a molten surface of the aluminum oxide is maintained between 2050° C. and 2060° C. A sapphire seed crystal is placed into the molten aluminum oxide from the molten surface, so that the sapphire seed crystal is in contact with the molten surface. Next, the sapphire seed crystal is slowly pulled so that sapphire crystal is grown to have desired diameter and length. The sapphire crystal is pulled out of the molten aluminum oxide at a constant speed, so that the sapphire crystal grows uniformly and that the diameter thereof remains constant. Then, the sapphire crystal is continuously pulled such that the diameter of an end portion of the sapphire crystal is gradually reduced until the sapphire crystal is completely separated from the molten aluminum oxide. After being separated from the molten aluminum oxide, the sapphire crystal is cooled and a sapphire ingot is thus obtained. The sapphire ingot is then cut using a multi-wire cutting machine to obtain a plurality of sapphire substrates 100.

In step S02, a single-sided surface treatment or a double-sided surface treatment may be adopted for each of the substrates 100. The single-sided surface treatment mainly includes applying the surface-treating agent 200 on one of the first surface 101 and the second surface 102 of each of the substrates 100. The surface-treating agent 200 may include a softening agent and a catalyst. In some embodiments, the surface-treating agent 200 may further include an anti-sticking agent. The softening agent includes at least one of an aluminate, a silicate, a carbonate, a hydroxide, an oxide or a halide, etc. The catalyst includes at least one of a reducing agent, an oxidizing agent, an acid, a base, or an ionic salt. The reducing agent may be, but not limited to, an element or a compound with low valence, such as carbon, silicon, sulfide, metal, iodide, or a ferrous salt. The oxidizing agent may be, but not limited to, a high-valence compound such as potassium permanganate, dichromate, chlorate, nitrate, a ferric salt, or a cupric salt. The anti-sticking agent may include e.g., an oxide, or the like. The oxide of the anti-sticking agent may have a melting point greater than that of the oxide of the softening agent. In certain embodiments, the melting point of the oxide of the anti-sticking agent may be greater than about 2000° C., and the melting point of the oxide of the softening agent may be less than about 1000° C. The softening agent, the catalyst and the optional anti-sticking agent are uniformly mixed to obtain the surface-treating agent 200. The thickness of the surface-treating agent 200 applied on each of the substrates 100 may be determined according to the annealing parameters and the desired removal rate in subsequent abrasing and polishing steps.

In some embodiments, the step S02 of performing the surface treatment includes applying the surface-treating agent 200 on the at least one of the first surface 101 and the second surface 102 of each of the substrates 100. After applying the surface-treating agent 200, the substrates 100 are heated and then stacked.

To be specific, after the surface-treating agent 200 is applied on the substrates 100, the substrates are heated (e.g., baked). In some embodiments, the substrates 100 are heated at a temperature ranging from 100° C. to 200° C. for a time period not greater than 2 hours. During this heating step, the surface-treating agent 200 is partially dried so as to be closely attached to the substrates 100, which facilitates reaction of the surface-treating agent 200 with the substrates 100 in the subsequent step. In the heating step, the surface-treating agent 200 only slightly reacts with or does not react with the substrates 100.

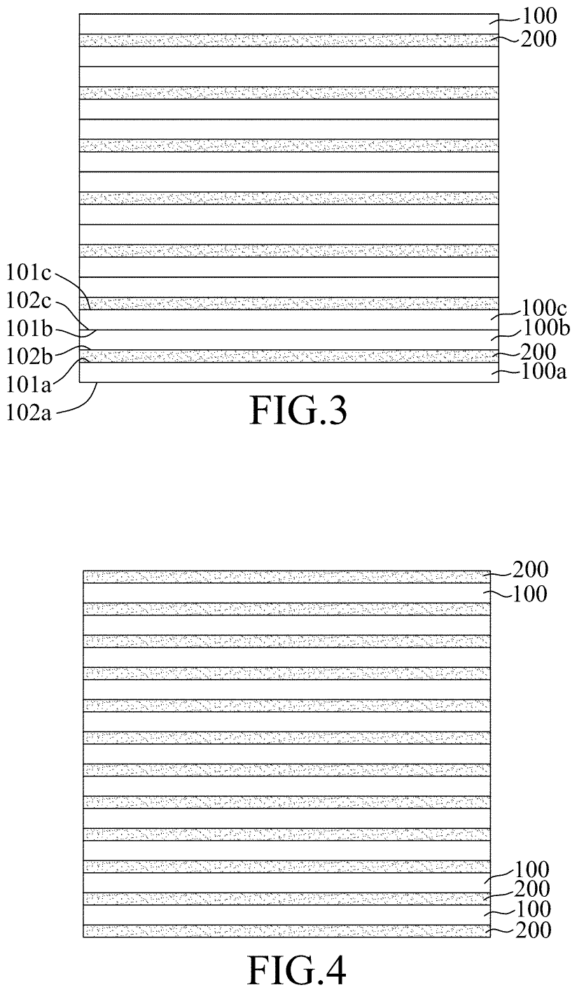

After the heating step, the substrates 100 are stacked to obtain a laminate structure (as shown in FIGS. 3 and 4).

FIG. 3 shows a first stacking example of the substrates 100. In FIG. 3, before the heating step, each of the substrates 100 is subjected to the single-sided surface treatment so that one of the first surface 101 and the second surface 102 of each of the substrates 100 is applied with the surface-treating agent 200. Three of the substrates 100 (i.e., first substrate 100a, second substrate 100b and third substrate 100c) are used to clearly illustrate the single-sided surface treatment and the way of stacking the substrates 100. The first substrate 100a has opposite first and second surfaces 101a, 102a, the second substrate 100b has opposite first and second surfaces 101b, 102b, and the third substrate 100c has opposite first and second surfaces 101c, 102c. In this embodiment, the first surface 101a of the first substrate 100a, the second surface 102b of the second substrate 100b, and the first surface 101c of the third substrate are applied with the surface-treating agent 200, followed by heating the substrates 100a, 100b, 100c. (i.e., the heating step). Then, the second substrate 100b is stacked on the first substrate 100a, with the second surface 102b (i.e., the surface applied with the surface-treating agent 200) of the second substrate 100b being in contact with the surface-treating agent 200 on the first substrate 100a. Then, the third substrate 100c is stacked on the second substrate 100b, with the second surface 102c (i.e., the surface not applied with the surface-treating agent 200) of the third substrate 100c being in contact with the first surface 101b (i.e., the surface not applied with the surface-treating agent 200) of the second substrate 100b. Other substrates 100 are applied with the surface-treating agent 200 and stacked in this way to form a laminate structure, as shown in FIG. 3.

FIG. 4 shows a second stacking example of the substrates 100. In FIG. 4, before the heating step, each of the substrates 100 is subjected to the double-sided surface treatment so that the first surface 101 and the second surface 102 of each of the substrates 100 are applied with the surface-treating agent 200. Then, the substrates 100 are subjected to the aforesaid heating step. Afterward, the substrates 100 are stacked to form a laminate structure with the surface-treating agent 200 as shown in FIG. 4. Thereafter, the substrates 100 and the surface-treating agent 200 are sequentially stacked in this way so as to form a laminate structure shown in FIG. 4.

After obtaining the laminate structure, the step S03 of annealing the substrates 100 is performed. In this embodiment, the step S03 of annealing the substrates includes: placing the laminate structure of the substrates 100 subjected to the surface treatment into a heating furnace; and annealing the substrates so as to obtain the annealed substrates 110. In some embodiments, the annealing temperature ranges from 30° C. to 3000° C., and the annealing time ranges from about 0.1 hour to about 30 days.

In some embodiments, annealing the substrates 100 mainly includes a heating stage, a holding stage, and a cooling stage. In the heating stage, the heating furnace is heated to a temperature ranging from 100° C. to 2000° C. at a heating rate of 0.5° C./min to 200° C./min. In the holding stage, the temperature of the heating furnace is maintained between 100° C. and 2000° C. for 0.1 hour to 500 hours. In the cooling stage, the heating furnace is cooled to room temperature at a cooling rate ranging between 0.5° C./min and 200° C./min. In this embodiment, the heating furnace is heated to a temperature that ranges between 1300° C. and 1800° C. at a heating rate of 1° C./min to 20° C./min, is maintained at a temperature between 1300° C. and 1800° C. for 1 to 100 hours, and is then cooled to room temperature at the cooling rate of 1° C./min to 20° C./min.

During the aforementioned holding stage, the surface-treating agent 200 reacts with the substrates 100. In some embodiments, when the softening agent of the surface-treating agent 200 is calcium carbonate (CaCO₃), the softening agent (CaCO₃) undergoes a decomposition reaction (CaCO₃→CaO+CO₂) during the holding stage. The reaction product, CaO, has high reactivity and is likely to react with the substrates 100 under high temperature. In some embodiments, when the substrates 100 are sapphire substrates, the following reaction occurs during the holding stage: CaO+Al₂O₃→xCaO.yAl₂O₃. In this reaction, x and y are both greater than zero, and different combinations of x and y values represent different reaction products. Under the high temperature of the holding stage, multiple reaction products may be obtained.

During step S03, the softening agent in the surface-treating agent 200 reacts with the substrates 100 at the first surfaces 101 and/or the second surfaces 102 of the substrates 100 in the presence of the catalyst so as to form a modified layer 1102 (see FIG. 5). The softening agent diffuses into and gradually reacts with each of the substrates 100 such that the thickness of the modified layer 1102 continues to be increased. By controlling the temperature and time of the holding stage, the thickness of the modified layer 1102 can be controlled. The thickness of the modified layer 1102 may be determined by the removal rate of the subsequent abrasing and polishing steps. In certain embodiments, the thickness of the modified layer 1102 ranges from greater than 0% to less than 100% of the thickness of the annealed substrate 110.

Compared to the untreated sapphire substrates, the modified layer 1102 containing the aforementioned reaction products has a Mohs hardness of about 6 to 7, which is relatively low. In addition, as shown in FIG. 6A, a surface structure of each of the untreated substrates 100 is dense and smooth. In contrast, as shown in FIG. 6B, after each of the substrates 100 are treated and annealed (i.e., subjected to the surface treatment and annealing of the present disclosure), the surface structure thereof becomes rough and loose. Such a rough and loose structure is relatively easier to be removed as compared to the dense and smooth structure. In the meantime, due to the difference in lattice and thermodynamic properties between the modified layer 1102 and the base 1101, the lattice constant of the annealed substrates 110 and the thermal stress in epitaxial growth can be adjusted. Thus, the annealed substrate 110 and an epitaxial layer formed thereon later are more closely matched in crystallinity and the lattice mismatch therebetween is reduced, which is conducive to improving the quality of the epitaxial layer.

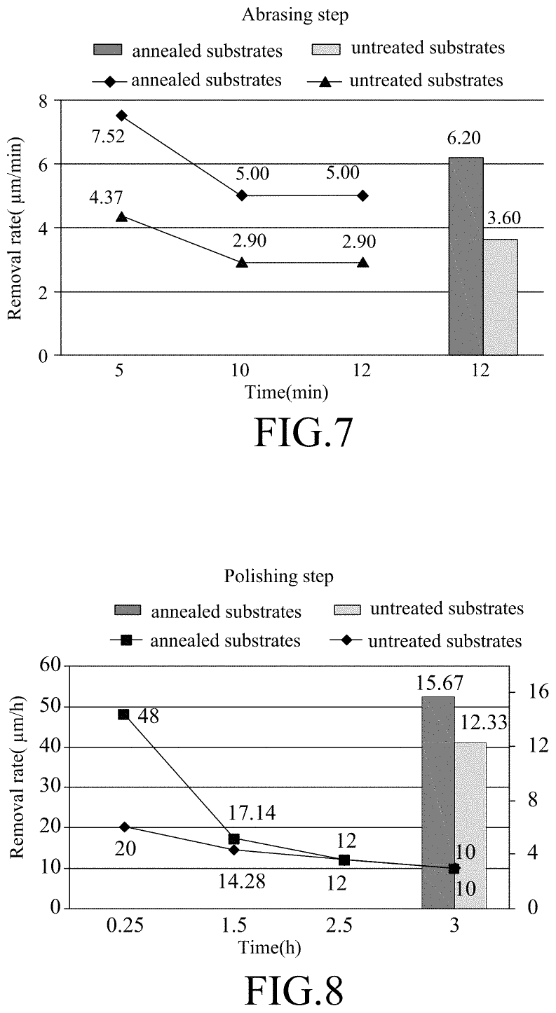

After annealing the substrates 100, each of the annealed substrates 110 undergoes an abrasing step (step S4). In order to verify the importance of the surface treatment and annealing steps in improving the removal rate of the annealed substrates 110, the annealed substrates 110 and untreated substrates (i.e., control group not subjected to the surface treatment and annealing steps) were abrased using the same parameters. The results are shown in FIG. 7.

FIG. 7 shows the removal rates of the two groups of substrates (i.e., the annealed substrates 110 and the untreated substrates) at different times during the abrasing step, and the total removal rate of the two groups of substrates in the abrasing step. It can be seen from FIG. 7 that, compared with the control group (i.e., untreated substrates), the removal rate of the annealed substrates 110 is significantly improved. In the first 5 minutes of the abrasing step, the removal rate of the annealed substrates 110 reached 7.52 μm/min, while the removal rate of the untreated substrates were only 4.37 μm/min. In addition, during the time period from fifth to tenth minute in the abrasing step, the removal rate of the annealed substrates 110 decreased from 7.52 μm/min to 5.0 μm/min, while the removal rate of the untreated substrates decreased from 4.37 μm/min to 2.90 μm/min. During the time period from tenth to twelfth minute in the abrasing step, the removal rate of the annealed substrates 110 is maintained at 5.0 μm/min, while the removal rate of the untreated substrates is maintained at 2.90 μm/min. Throughout the abrasing step, the total removal rate of the annealed substrates 110 can reach as high as 6.20 μm/min, while the total removal rate of the untreated substrates is only 3.60 μm/min. It can be seen that the removal rate of the annealed substrates 110 of the present disclosure is significantly improved. That is, the surface treatment of the present disclosure significantly reduces the difficulty of processing the substrate, which is conducive to saving abrasing time and improving production efficiency.

In this embodiment, after the abrasing step, the method for making the semiconductor substrate of the present disclosure further includes: cleaning each of the annealed substrates 110 to remove impurities remaining on the surface of each of the annealed substrates 110 and polishing each of the annealed substrates 110 after cleaning.

The removal rates of the two groups of substrates (i.e., the annealed substrates 110 and the untreated substrates) at different times during the polishing step and the total removal rates of the two groups of substrates after polishing are shown in FIG. 8. It can be seen from FIG. 8 that, compared with the untreated substrates, the removal rate of the annealed substrates 110 is significantly improved during the polishing step. For example, during the first 0.25 hours, the removal rate of the annealed substrates 110 reached 48 μm/hr, while the removal rate of the untreated substrates was only 20 μm/hr. In addition, during the time period from 0.25 hours to 1.5 hours in the polishing step, the removal rate of the annealed substrates 110 decreased from 48 μm/hr to 17.14 μm/hr, while the removal rate of the untreated substrates decreased from 20 μm/hr to 14 μm/hr. Moreover, during the time period from 2.5 h to 3 h in the polishing step, the removal rates of the annealed substrates 110 of the present disclosure and the untreated substrates are almost the same. Throughout the polishing step, the total removal rate of the annealed substrates 110 reached 15.67 μm/hr, while the removal rate of the untreated substrate was 12.33 μm/hr. It can be seen that, in the polishing step, the removal rate of the annealed substrates 110 subjected to the surface treatment of the present disclosure is significantly improved. That is, the processing difficulty of the substrate is significantly reduced, which is conducive to saving polishing time and improving production efficiency.

It should be noted that, the step of abrasing the annealed substrates 110 may be conducted to partly remove the modified layer 1102 from each of the annealed substrates 110 so as to leave a portion of the modified layer 1102 on the base 1101 of each of the annealed substrates 110. Similarly, polishing the annealed substrates 110 may be conducted to partly remove the modified layer 1102 from each of the annealed substrates 110 so as to leave a portion of the modified layer 1102 on the base 1101 of each of the annealed substrates 110.

The results in FIGS. 7 and 8 revealed that the removal rates of the annealed substrates 110 in the abrasing step and the polishing step are significantly improved, which is beneficial for saving processing time of the substrate and increasing productivity. At the same time, a suitable surface-treating agent 200 can be selected according to the properties of the epitaxial layer formed in later processes, so that the properties of the modified layer 1102 thus formed on the base 1101 of each of the annealed substrates 110 are closer to those of the epitaxial layer, and the lattice mismatch between the annealed substrate 110 and the epitaxial layer can be reduced.

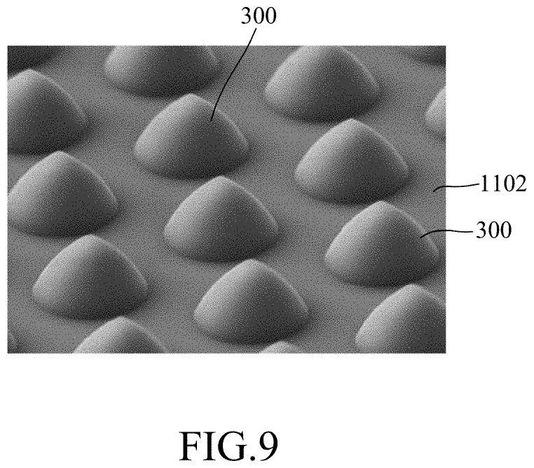

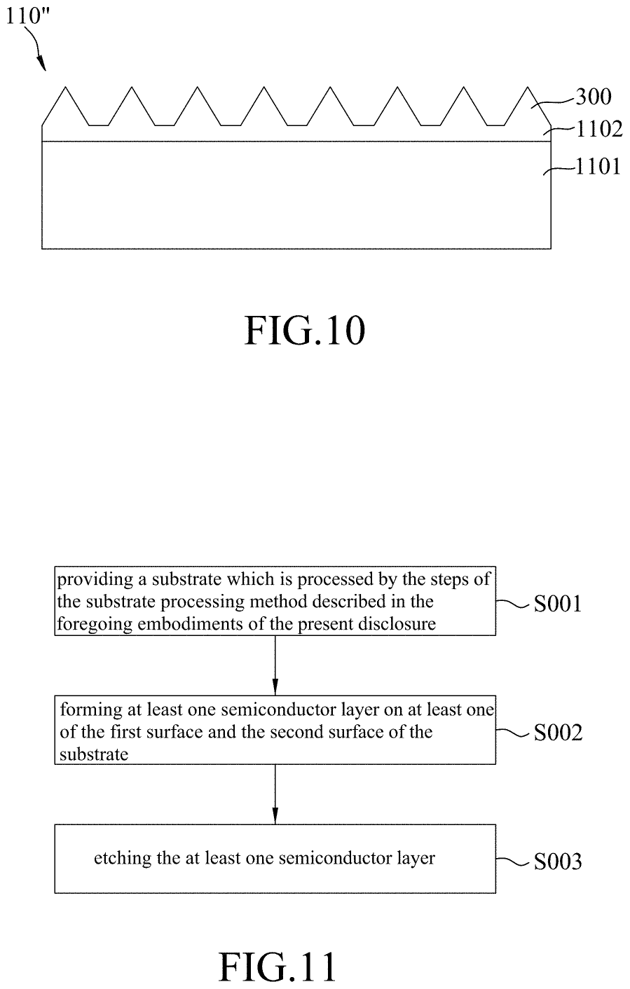

In some embodiments, as shown in FIG. 9, each of the annealed substrates 110 (e.g., a treated and annealed sapphire substrate) may be patterned to form a patterned substrate 110″ in order to facilitate the subsequent formation of the epitaxial layer. In certain embodiments, the modified layer 1102 of the annealed substrate 110 is patterned to form a plurality of protrusions 300 on the base 1101. As shown in FIG. 10, in the patterned substrate 110″, a very thin layer of the modified layer 1102 remains on the base 1101. Ca²⁺ ions can be found in both the protrusions 300 and the modified layer 1102, and the concentration of the Ca²⁺ ions in the patterned substrates 110″ is 25% higher than that in the untreated substrates, which has a very low concentration of Ca²⁺ ions (e.g., a relative concentration of Ca²⁺ ions in the untreated substrates ranges from about 10⁻¹² to about 10⁻¹¹). Since the radius of Ca²⁺ ions is larger than that of Al³⁺, the Ca²⁺ ions remaining in the modified layer 1102 and the protrusions 300 can be used to adjust the lattice crystallinity of the patterned substrate 110″, making the patterned substrate 110″ match the epitaxial layer and reducing the lattice mismatch. In addition, experimental results confirm that the total of a thickness of the modified layer 1102 and a thickness of the protrusions 300 measured from an interface between the modified layer 1102 and the protrusions 300 is in the range of 3 μm to 30 μm. This thickness range will not affect the formation of the epitaxial layer, nor will it affect the quality of the epitaxial layer.

A method for making a semiconductor device using the annealed substrates 110 is disclosed hereinafter. As shown in FIG. 11, the method includes the following steps:

Step S001: providing the aforesaid annealed substrate 110;

Step S002: forming at least one semiconductor layer on the annealed substrate 110; and

Step S003: etching the at least one semiconductor layer.

As disclosed in the embodiments above, the annealed substrate 110 of the present disclosure has been subjected to the surface treatment step, the annealing step, and the abrasing step. In some embodiments, the annealed substrate 110 of the present disclosure may be the one further subjected to cleaning and polishing steps after the abrasing step.

The material of the annealed substrate 110 is described above. In this embodiment, the substrate 100 is a sapphire substrate. In step S002, forming the at least one semiconductor layer includes the sub-steps of: first, forming a first semiconductor layer on the annealed substrate 110, and then forming an active layer on the first semiconductor layer, followed by forming a second semiconductor layer on the active layer. The second semiconductor layer has a conductivity opposite to that of the first semiconductor layer. In addition, in some embodiments, formation of the at least one semiconductor layer further includes forming a first electrode and a second electrode that are electrically connected to the first semiconductor layer and the second semiconductor layer, respectively.

In certain embodiments, the first semiconductor layer may be an N-type semiconductor layer, and the second semiconductor layer may be a P-type semiconductor layer. In certain embodiments, the first semiconductor layer may be a P-type semiconductor layer, and the second semiconductor layer may be an N-type semiconductor layer. The active layer may be a multiple quantum well. In certain embodiments, the at least one semiconductor layer may be etched so as to form a semiconductor light-emitting structure.

In the method for making the semiconductor device and the method for making the semiconductor substrate of the present disclosure, after the substrates 100 are cut from the ingot, the substrates 100 are subjected to surface treatment and annealing. The surface-treating agent 200 may include the softening agent and the catalyst. In some embodiments, the surface-treating agent further includes the anti-sticking agent. During annealing, in the presence of the catalyst, the softening agent in the surface-treating agent 200 reacts with the substrates 100 to form the modified layer 1102. The loose structure of the modified layer 1102 reduces the strength/hardness of the annealed substrate 110 so as to significantly improve abrasing and polishing efficiency, and to reduce the processing difficulty of the annealed substrates 110. Taking the sapphire substrate as an example, after performing the abovementioned surface treatment and annealing, the total removal rate thereof in the abrasing step can reach 6.20 μm/min, and the total removal rate in the polishing step can reach 15.67 μm/hr. The improved removal rates is conducive to improving production efficiency and reducing costs.

In addition, by adjusting the temperature and time in the annealing step, the degree of reaction between the surface-treating agent 200 and the substrates 100 can be controlled so as to control the thickness of the modified layer 1102.

Moreover, as mentioned above, the modified layer 1102 may not be completely removed and can remain on the base layer 1101 of the annealed substrate 110 to adjust the lattice structure of the annealed substrates 110 and the thermal stress in epitaxial growth, so as to reduce lattice mismatch and thermal mismatch. At the same time, by selecting a suitable surface-treating agent 200, the modified layer 1102 may have properties similar to those of the epitaxial layer.

In the description above, for the purposes of explanation, numerous specific details have been set forth in order to provide a thorough understanding of the embodiments. It will be apparent, however, to one skilled in the art, that one or more other embodiments may be practiced without some of these specific details. It should also be appreciated that reference throughout this specification to “one embodiment,” “an embodiment,” an embodiment with an indication of an ordinal number and so forth means that a particular feature, structure, or characteristic may be included in the practice of the disclosure. It should be further appreciated that in the description, various features are sometimes grouped together in a single embodiment, figure, or description thereof for the purpose of streamlining the disclosure and aiding in the understanding of various inventive aspects, and that one or more features or specific details from one embodiment may be practiced together with one or more features or specific details from another embodiment, where appropriate, in the practice of the disclosure.

While the disclosure has been described in connection with what are considered the exemplary embodiments, it is understood that this disclosure is not limited to the disclosed embodiments but is intended to cover various arrangements included within the spirit and scope of the broadest interpretation so as to encompass all such modifications and equivalent arrangements.

What is claimed is:

1. A method for making a semiconductor substrate, comprising:
cutting an ingot to obtain a plurality of substrates, each of the substrates including a first surface and a second surface opposite to the first surface;
performing a surface treatment on at least one of the first surface and the second surface of each of the substrates using a surface-treating agent;
annealing the substrates so that the substrates react with the surface-treating agent to obtain annealed substrates, each of the annealed substrates having a base and a modified layer formed by a reaction between a corresponding one of the substrates and the surface-treating agent; and
abrasing each of the annealed substrates to remove at least a part of the modified layer.

2. The method according to claim 1, wherein the step of performing the surface treatment includes:
(i) applying the surface-treating agent on the at least one of the first surface and the second surface of each of the substrates;
(ii) after step (i), heating the substrates at a temperature ranging from 100° C. to 200° C. for a time period not greater than 2 hours; and
(iii) stacking the substrates.

3. The method according to claim 1, wherein the step of annealing the substrates includes:
placing the substrates subjected to the surface treatment into a heating furnace; and
annealing the substrates at a temperature ranging from 30° C. to 3000° C. for 0.1 hours to 30 days.

4. The method according to claim 3, wherein the step of annealing the substrates includes:
heating the heating furnace to a temperature ranging between 100° C. and 2000° C. at a heating rate ranging from 0.5 to 200° C./min;
maintaining the heating furnace at the temperature ranging between 100 and 2000° C. for 0.1 hours to 500 hours; and
cooling the heating furnace to room temperature at a cooling rate ranging from 0.5 to 200° C./min.

5. The method according to claim 1, wherein the modified layer has a thickness not greater than that of a corresponding one of the substrates on which the modified layer is formed.

6. The method according to claim 1, wherein:
before the step of performing the surface treatment, mixing a softening agent and a catalyst to obtain the surface-treating agent.

7. The method according to claim 6, wherein:
the softening agent is at least one of an aluminate, a silicate, a carbonate, a hydroxide, an oxide, or a halide; and
the catalyst is at least one of a reducing agent, an oxidizing agent, an acid, a base, or an ionic salt.

8. The method according to claim 7, wherein:
the reducing agent is at least one of a carbon, a silicon, a sulfide, a metal, an iodide, or a ferrous salt; and
the oxidizing agent is at least one of potassium permanganate, a dichromate, a chlorate, a nitrate, a ferric salt, or a cupric salt.

9. The method according to claim 1, further comprising:
after abrasing the annealed substrates, cleaning the annealed substrates; and
polishing the annealed substrates after cleaning.

10. The method according to claim 1, wherein the modified layer has a looser structure than that of the base.

11. The method according to claim 1, wherein abrasing the annealed substrates is conducted to partly remove the modified layer from each of the annealed substrates so as to leave a portion of the modified layer on the base of each of the annealed substrates.

12. A method for making a semiconductor device, comprising the steps of:
a) providing a semiconductor substrate which is processed by the sub-steps of:
a1) cutting an ingot to obtain a plurality of substrates, each of the substrates including a first surface and a second surface opposite to the first surface,
a2) performing a surface treatment on at least one of the first surface and the second surface of each of the substrates using a surface-treating agent,
a3) annealing the substrates so that the substrates react with the surface-treating agent to obtain annealed substrates, each of the annealed substrates having a base and a modified layer formed by a reaction between a corresponding one of the substrates and the surface-treating agent, and
a4) abrasing each of the annealed substrates to remove at least a part of the modified layer;
b) forming at least one semiconductor layer on the semiconductor substrate; and
c) etching the at least one semiconductor layer.

13. The method according to claim 12, wherein step b) includes the sub-steps of:
b1) forming a first semiconductor layer on the semiconductor substrate;
b2) forming an active layer on the first semiconductor layer; and
b3) forming a second semiconductor layer on the active layer, the second semiconductor layer having a conductivity opposite to that of the first semiconductor layer.

14. The method according to claim 12, further comprising:
d) forming a first electrode and a second electrode that are respectively electrically connected to the first semiconductor layer and the second semiconductor layer.

15. The method according to claim 12, wherein step a2) includes:
(i) applying the surface-treating agent on the at least one of the first surface and the second surface of each of the substrates;
(ii) heating the substrates at a temperature ranging from 100° C. to 200° C. for a time period not greater than 2 hours; and
(iii) stacking the substrates.

16. The method according to claim 12, wherein step a3) includes:
placing the substrates subjected to the surface treatment into a heating furnace; and
annealing the substrates at a temperature ranging from 30° C. to 3000° C. for 0.1 hours to 30 days.

17. The method according to claim 16, wherein the step of annealing the substrates includes:
heating the heating furnace to a temperature ranging between 100° C. and 2000° C. at a heating rate ranging from 0.5 to 200° C./min;
maintaining the heating furnace at the temperature ranging between 100 and 2000° C. for 0.1 hours to 500 hours; and
cooling the heating furnace to room temperature at a cooling rate ranging from 0.5 to 200° C./min.

18. The method according to claim 12, wherein the modified layer has a thickness not greater than that of a corresponding one of the substrates on which the modified layer is formed.

19. The method according to claim 12, wherein:
before step a2), mixing a softening agent and a catalyst to obtain the surface-treating agent.

20. The method according to claim 12, wherein step a) further includes the steps of:
after abrasing the annealed substrates, cleaning the annealed substrates; and
polishing the annealed substrates after cleaning.
